(19) United States
(12) Patent Application Publication
(10) Pub. No.: US 2026/0305175 A1
(43) Pub. Date: Oct. 1, 2026

(54) STACKED PIEZOELECTRIC CERAMIC COMPONENT AND DEVICE INCLUDING THE SAME

(71) Applicant: Niterra Co., Ltd., Nagoya-shi, Aichi (JP)

(72) Inventors: Yoshinobu HIROSE, Nagoya-shi (JP); Kentaro ICHIHASHI, Nagoya-shi (JP); Masato YAMAZAKI, Nagoya-shi (JP)

(73) Assignee: Niterra Co., Ltd., Nagoya-shi, Aichi (JP)

(21) Appl. No.: 19/479,627

(22) PCT Filed: Nov. 7, 2024
(86) PCT No.: PCT/JP2024/039523

§ 371 Date: Oct. 28, 2025

(30) Foreign Application Priority Data
Mar. 15, 2024 (JP) 2024-040605

(51) Int. Cl. H10N 30/50; H10N 30/20; H10N 30/30; H10N 30/853; H10N 30/87

(52) U.S. Cl. CPC H10N 30/50; H10N 30/20; H10N 30/302; H10N 30/8542; H10N 30/871; H10N 30/877

(57) ABSTRACT

A stacked piezoelectric ceramic component (10) includes a stacked body (20) which includes a plurality of electrodes (12, 13) and piezoelectric ceramic layers (11) stacked such that each of the electrodes (12, 13) is disposed between the piezoelectric ceramic layers, the piezoelectric ceramic layers containing alkali niobate-based perovskite-type oxide as a main component. In the stacked piezoelectric ceramic component (10), a portion of the piezoelectric ceramic layers (11), which portion is not sandwiched between the plurality of stacked electrodes (12, 13) serves as a non-active layer (21). The non-active layer (21) has a thickness of 25 μm or greater.

### TECHNICAL FIELD

The present invention relates to a stacked piezoelectric ceramic component, and to a device including the component.

### BACKGROUND ART

In recent years, attention has been paid to an actuator including a stacked piezoelectric ceramic component which is compact and which can be provide considerable displacement even through application of low voltage. A typical stacked piezoelectric ceramic component includes a PZT-type (lead titanate zirconate-based) piezoelectric ceramic body and internal electrodes containing, for example, Pt, Pd, or the like. However, such a PZT-type piezoelectric ceramic material is problematic, since the ceramic material contains lead, which adversely affects the environment. In addition, metallic materials such as Pt and Pd are expensive, which is also problematic.

Under such circumstances, there is increasing demand for a low-cost, environmental-friendly stacked piezoelectric ceramic component. Indeed, there has been proposed a lead-free stacked piezoelectric ceramic component having a piezoelectric ceramic part formed of a lead-free material and internal electrodes mainly formed of Ni (i.e., a base metal), which is less expensive than Pt or Pd (see, for example, Patent Documents 1 and 2).

Patent Documents 1 and 2 each disclose a stacked piezoelectric ceramic component which includes internal electrodes formed of Ni as a main component, and piezoelectric ceramic layers formed of an alkali niobate-based perovskite-type oxide as a main component, wherein the electrodes and the ceramic layers are alternatingly stacked.

### PRIOR ART DOCUMENTS

### Patent Documents

Patent Document 1: Japanese Patent No. 5862983
Patent Document 2: Japanese Patent No. 6094682

### SUMMARY OF THE INVENTION

### Problems to be Solved by the Invention

In some cases, an actuator including a stacked piezoelectric ceramic component may be used under high-temperature and strong-electric field conditions (e.g., 100° C. and 3 kV/mm). Thus, there is demand for a stacked piezoelectric ceramic component that can exhibit suitable insulation property even under severe conditions (i.e., high-temperature and strong-electric field conditions).

In view of the foregoing, an object of the present invention to provide a stacked piezoelectric ceramic component that can exhibit a consistently high insulation property at high temperature and under a strong electric field. Another object is to provide a device including the stacked piezoelectric ceramic component.

### Means for Solving the Problems

[1]

In one aspect of the present invention, there is provided a stacked piezoelectric ceramic component comprising a stacked body which includes a plurality of electrodes and piezoelectric ceramic layers stacked such that each of the electrodes is disposed between the piezoelectric ceramic layers, the piezoelectric ceramic layers containing an alkali niobate-based perovskite-type oxide as a main component. In the piezoelectric ceramic layer, a portion of the piezoelectric ceramic layers, which portion is not sandwiched between the plurality of stacked electrodes, serves as a non-active layer, and the non-active layer has a thickness of 25 μm or greater.

According to the aforementioned configuration, the thickness of the non-active layer is adjusted to be 25 μm or greater, to thereby provide a stacked piezoelectric ceramic component exhibiting suitable insulation property at high temperature and under a strong electric field.

[2]

In the stacked piezoelectric ceramic component according to the aspect of the present invention as described in [1] above, the electrodes may contain nickel as a main component.

According to the aforementioned technical means, a stacked piezoelectric ceramic component can be produced at lower cost.

[3]

In the stacked piezoelectric ceramic component according to the aspect of the present invention as described in [1] or [2] above, the non-active layer may have a thickness of 100 μm or greater.

According to the aforementioned technical means, the thickness of the non-active layer is adjusted to be 100 μm or greater, whereby the insulation property of the stacked piezoelectric ceramic component can be further enhanced.

[4]

In the stacked piezoelectric ceramic component according to the aspect of the present invention as described in [3] above, the non-active layer may have a thickness of 200 μm or greater and 2,000 μm or smaller.

According to the aforementioned technical means, the thickness of the non-active layer is adjusted to be 200 μm or greater, whereby the insulation property of the stacked piezoelectric ceramic component can be further enhanced. Also, by adjusting the thickness of the non-active layer to 2,000 μm or smaller, a drop in mechanical strength of the stacked piezoelectric body can be suppressed.

[5]

In the stacked piezoelectric ceramic component according to the aspect of the present invention as described in any of [1] to [4] above, the piezoelectric ceramic layer may contain a primary phase component containing the alkali niobate-based perovskite-type oxide, and a secondary phase component containing an oxide containing manganese and titanium.

According to the aforementioned technical means, an oxide containing manganese and titanium serving as the second phase component is incorporated into the piezoelectric ceramic layer containing an alkali niobate-based perovskite oxide serving as the primary phase component, to thereby yield a dense piezoelectric ceramic layer with higher reliability.

[6]

In the stacked piezoelectric ceramic component according to the aspect of the present invention as described in [5] above, the alkali niobate-based perovskite-type oxide may include manganese and titanium.

According to the aforementioned technical means, the insulation property of the piezoelectric ceramic layer can be further enhanced by incorporating manganese into the alkali niobate-based perovskite-type oxide. Also, the piezoelectric property of the piezoelectric ceramic layer can be enhanced by incorporating titanium into the alkali niobate-based perovskite-type oxide.

[7]

In the stacked piezoelectric ceramic component according to the aspect of the present invention as described in [6] above, the alkali niobate-based perovskite-type oxide may further include scandium.

According to the aforementioned technical means, the insulation property of the piezoelectric ceramic layer can be further enhanced by incorporating scandium into the alkali niobate-based perovskite-type oxide.

[8]

In another aspect of the present invention, there is provided a device including a stacked piezoelectric ceramic component as recited in any of [1] to [7].

[9]

The device according to [8] above may be any of an actuator, a haptic device, a buzzer, and an ultrasonic sensor.

When the device according to another aspect of the present invention has a stacked piezoelectric ceramic component that can provide a consistently high insulation property at high temperature and under a strong electric field, the device can exhibit consistently suitable property even under severe conditions (i.e., high-temperature and strong-electric field conditions).

### Advantageous Effects of Invention

According to one aspect of the present invention, there can be provided a stacked piezoelectric ceramic component that can exhibit consistently high insulation property at high temperature and under a strong electric field.

### BRIEF DESCRIPTION OF THE DRAWINGS

FIG. 1 is a schematic view showing the sectional structure of a stacked piezoelectric ceramic component according to one embodiment.

FIG. 2 is a perspective view schematically showing the structure of the stacked piezoelectric ceramic component shown in FIG. 1.

FIG. 3 is a schematic view used for describing the dimensions, etc. of a stacked body which constitutes the stacked piezoelectric ceramic component.

FIG. 4 is a schematic view showing the configuration of a vertical cross section (cut surface along the thickness direction) of a stacked piezoelectric ceramic component fabricated in an example.

FIG. 5 is a schematic view showing an actuator, which is one example of a device.

FIG. 6 is a schematic view showing a tablet terminal equipped with haptics, which is one example of the device.

FIG. 7 is a schematic view showing a buzzer, which is one example of the device.

FIG. 8 is a schematic view showing an ultrasonic sensor, which is one example of the device.

### MODES FOR CARRYING OUT THE INVENTION

An embodiment of the present invention will now be described with reference to the drawings. In the present embodiment, a stacked piezoelectric ceramic component 10 will be described as one example. The stacked piezoelectric ceramic component 10 is used as, for example, piezoelectric elements of devices such as an actuator, haptics, a buzzer, and an ultrasonic sensor.

### (Structure of Stacked Piezoelectric Ceramic Component)

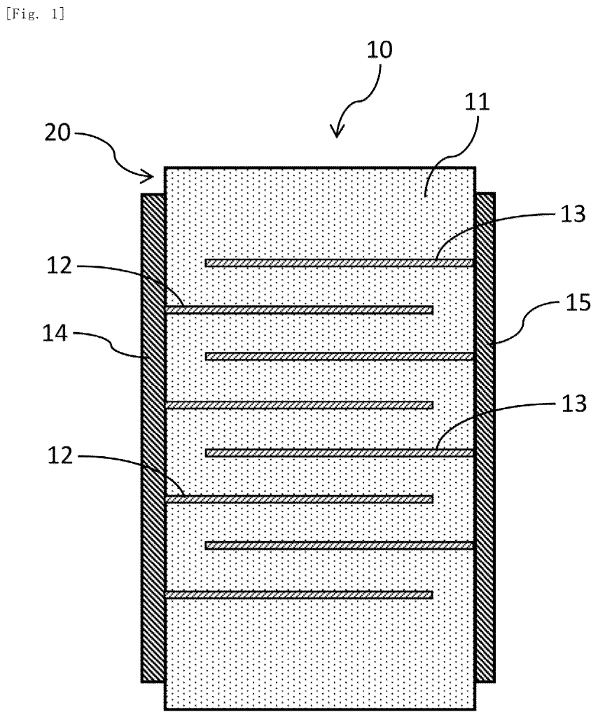

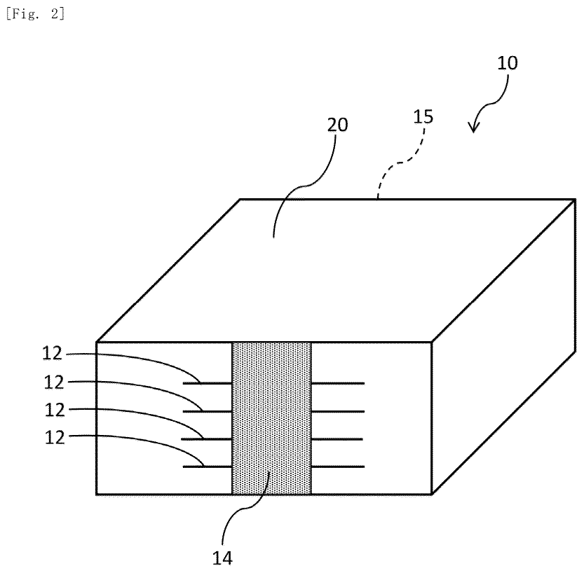

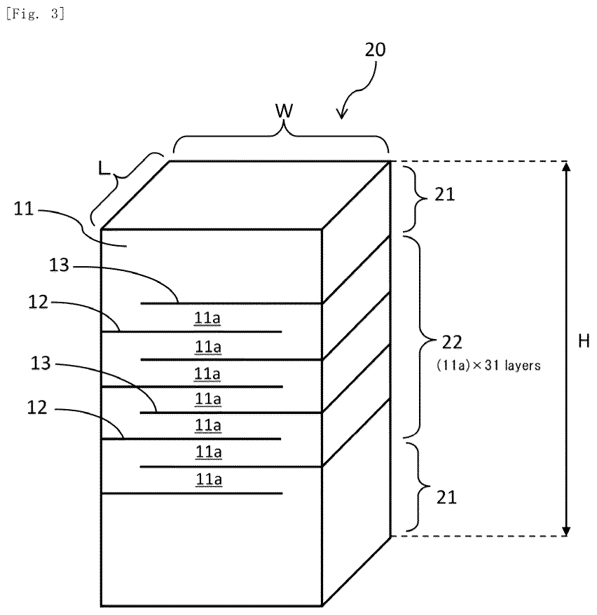

FIG. 1 shows the sectional structure of the stacked piezoelectric ceramic component 10. FIG. 2 schematically shows the appearance of the stacked piezoelectric ceramic component 10. FIG. 3 schematically shows the structure of a stacked body 20 which constitutes the stacked piezoelectric ceramic component 10.

The stacked piezoelectric ceramic component 10 includes piezoelectric layers (piezoelectric ceramic layers) 11, a plurality of internal electrodes (electrodes) 12 and 13 disposed in the piezoelectric layers 11, and external electrodes 14 and 15. The plurality of internal electrodes (electrodes) 12 and 13 are disposed in such a manner that each internal electrode is stacked between two piezoelectric layers 11, thereby forming the stacked body 20. The surfaces of the internal electrodes 12 and 13 are in contact with the piezoelectric layers 11.

Each piezoelectric layer 11 contains an alkali niobate-based perovskite-type oxide as a main component. As used herein, the expression “contain as a main component” refers to that the amount of the component is the largest in the composition of the piezoelectric layer 11 by the unit of vol. % (volume ratio).

Each of the internal electrodes 12 and 13 contains a base metal as a main component. Specifically, each of the internal electrodes 12 and 13 contains Ni (nickel) as a main component. As used herein, the expression “contains as a main component” means that the amount of the component is the largest in the composition of the each of the internal electrodes 12 and 13 by the unit of vol. % (volume ratio). Since each of the internal electrodes 12 and 13 contains Ni as a main component, the stacked piezoelectric ceramic component can be manufactured at a lower cost as compared with the case where electrodes containing other metals (for example, noble metals such as Pt (platinum) are used.

The piezoelectric layers 11 and the internal electrodes 12 and 13 are alternatingly stacked. More specifically, the piezoelectric layers 11 and the internal electrodes 12 and 13 are stacked in such a manner that one piezoelectric layer 11, one internal electrode 12, another piezoelectric layer 11, one internal electrode 13, another piezoelectric layer 11, etc. are stacked in this order. One piezoelectric layer 11 (this will be referred to as a “single layer 11a”) is sandwiched by two internal electrodes 12 and 13 (see FIG. 1).

The external electrodes 14 and 15 are disposed on the outer surface of the stacked body 20 composed of the piezoelectric layers 11 and the internal electrodes 12 and 13. For example, the external electrode 14 is disposed on one side surface of the stacked body 20 having an approximately cuboid shape. The external electrode 15 is disposed on the other side surface of the stacked body 20 opposite the side surface on which the external electrode 14 is disposed.

One end of one internal electrode selected from two internal electrodes 12 and 13 (the internal electrode 12 in the example shown in FIG. 1) in contact with each single layer 11a is connected to one external electrode 14, and one end of the other internal electrode (the internal electrode 13 in the example shown in FIG. 1) is connected to the other external electrode 15. When a voltage is applied between the two external electrodes 14 and 15, each single layer 11a expands and contracts, and thus, the entire stacked piezoelectric ceramic component 10 expands and contracts.

In the present embodiment, of the piezoelectric layers 11 which constitute the stacked body 20, a portion (layer) which is not sandwiched between the stacked internal electrodes 12 and 13 will be referred to as a non-active layer 21, and a portion (layer) which is sandwiched between the stacked internal electrodes 12 and 13 will be referred to as an active layer 22. In the present embodiment, the non-active layer 21 is provided in each of an uppermost layer portion and a lowermost layer portion of the stacked body 20 (see FIG. 3). However, in another embodiment, the non-active layer 21 may be provided in only one of the uppermost layer portion and the lowermost layer portion of the stacked body 20.

### (Composition of Piezoelectric Layer)

The composition of each piezoelectric layer 11 (hereinafter may also be referred to simply as “the piezoelectric layer 11”) will next be described. As mentioned above, the piezoelectric layer 11 contains an alkali niobate-based perovskite-type oxide as a main component.

More specifically, the piezoelectric layer 11 contains a primary phase component containing the alkali niobate-based perovskite-type oxide, and a secondary phase component containing an oxide containing manganese and titanium. The primary phase component forms a primary phase in the piezoelectric layer 11, and the secondary phase component forms a secondary phase in the piezoelectric layer 11. In the piezoelectric layer 11, a small amount of the secondary phase is co-present with a primary phase matrix.

Hereinafter, the alkali niobate-based perovskite oxide serving as a primary phase component will be described in detail. The piezoelectric layer 11 contains, as a main component, an alkali niobate-based perovskite-type oxide having a piezoelectric property. The alkali niobate-based perovskite-type oxide has a perovskite-type structure. Generally, a metal oxide having a perovskite-type structure is represented by a compositional formula ABO3 and is formed of a metal element in A sites, a metal element in B sites, and oxygen. In an ideal perovskite-type structure, 12 oxygen atoms coordinate to one metal element in A site, and 6 oxygen atoms coordinate to one metal element in B site. These unit structures are periodically arranged, to thereby form a crystal.

The alkali niobate-based perovskite-type oxide of the present embodiment preferably contains at least one member of alkali metal (e.g., potassium (K), sodium (Na), or lithium (Li)) as an alkali component in the A site, particularly preferably at least one of potassium (K) and sodium (Na). Also, the alkali niobate-based perovskite-type oxide preferably contains niobium (Nb) in the B site. The alkali niobate-based perovskite-type oxide may further contain, as an alkali component, an alkaline earth metal (at least one of calcium (Ca), strontium (Sr), barium (Ba), or the like) in the A site. Even when a part of the alkali component is present in the B site, or niobium is present in the A site, the effects of the present invention can be achieved.

Notably, since the piezoelectric layer 11 contains no lead (Pb), the aforementioned composition forming the piezoelectric layer 11 is also called a “lead-free piezoelectric composition.”

Preferably, the alkali niobate-based perovskite oxide is represented by the following compositional formula (1).

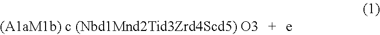

In the compositional formula (1), the element denoted by Nb is niobium. In the compositional formula (1), the element Al is an alkali metal which is at least one species of Li (lithium), Na (sodium), and K (potassium). In the compositional formula (2), the element M1 is an alkaline earth metal which is at least one species of Ba (barium), Ca (calcium), and Sr (strontium).

In the above compositional formula (1), the element Al and the element M1 are disposed in A sites of the perovskite structure, and Nb (niobium), Mn (manganese), Ti (titanium), and Zr (zirconium) are disposed in B sites.

In the compositional formula (1), coefficients a to e are selected from the values which are preferred from the viewpoints of electrical characteristics and piezoelectric characteristics of the lead-free piezoelectric composition, so long as the coefficients a to e ensure establishment of the perovskite structure.

Specifically, coefficients a and b satisfy the conditions: 0<a<1, 0<b<1, and a+b=1. However, the cases of a=0 (i.e., the composition containing no alkali metal) and b=0 (i.e., the composition containing none of Ba, Ca, and Sr) are excluded.

Coefficient c with respect to the entire A sites satisfies 0.80<c<1.10, and is preferably 0.90≤c≤1.05.

Coefficients d1, d2, d3, d4, and d5 satisfy the conditions: 0<d1<1, 0<d2<1, 0<d3<1, 0≤d4<1, and 0≤d5<1. However, the cases of d1=0 (i.e., the composition containing no Nb), d2=0 (i.e., the composition containing no Mn), and d3=0 (i.e., the composition containing no Ti) are excluded. Coefficient d4 to Zr may be 0 (i.e., any composition containing no Zr being acceptable). Coefficient d5 to Sc may be 0 (i.e., any composition containing no Sc being acceptable).

Notably, coefficient d1 to Nb preferably satisfies 0.830≤d1≤0.959. Coefficient d2 to Mn preferably satisfies 0.001≤d2≤0.10. Coefficient d3 to Ti preferably satisfies 0.005≤d3≤0.10. Coefficient d4 to Zr preferably satisfies 0≤d4≤0.20. Also, the equation d1+d2+d3+d4+d5=1 is preferably satisfied.

In coefficient (3+e) with respect to oxygen, the value of coefficient e is a positive or negative value showing deficiency or excess from the intrinsic value of 3 with respect to oxygen. Coefficient (3+e) with respect to oxygen may be a value which allows the primary phase to have a perovskite oxide structure. Typically, coefficient e is 0, and preferably satisfies 0≤e≤0.1. Notably, coefficient e may also be calculated from the composition of the primary phase to meet the electrically neutral condition. However, needless to say, a composition of the primary phase which is slightly deviated from the electrically neutral condition is also allowable.

The piezoelectric layer 11, which contains the alkali niobate-based perovskite oxide represented by the aforementioned compositional formula (1), achieves more excellent piezoelectric characteristics and insulation property.

More specifically, the alkali niobate-based perovskite-type oxide preferably contains Mn and Ti. By adding a specific amount of Mn, the added Mn serves as an acceptor and enters Nb sites to form a solid solution, thereby providing oxygen vacancies. Thus, the insulation property is enhanced. Also, conceivably, by adding a specific amount of Ti, the crystal structure is modified, to thereby enhance piezoelectric characteristics.

In the aforementioned compositional formula (1), more preferably, the case of d5=0 (i.e., the composition containing no Sc) is excluded. In other words, the condition 0<d5<1 is more preferred. Still more preferably, coefficient d5 to Sc satisfies a condition 0.0002≤d5≤0.10.

As mentioned above, Sc is joined into the compositional formula (1). Thus, conceivably, Sc serves as an acceptor to suppress generation of carries, whereby the insulation property can be further enhanced.

More preferably, the alkali niobate-based perovskite oxide is represented by the following compositional formula (2).

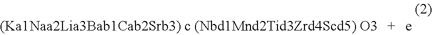

The compositional formula (2) is equivalent to the formula (1), and the conditions: alta2+a3=a and b1+b2+b3=b are satisfied. Coefficient a1 with respect to K is 0<a1≤0.7 (preferably 0.095≤a1≤0.665); coefficient a2 with respect to Na is 0<a2≤0.9 (preferably 0.285≤a2≤0.855); and coefficient a3 with respect to Li is 0≤a3≤0.2 (preferably 0≤a3≤0.1). Also, coefficient b1 with respect to Ba is 0≤b1≤0.2 (preferably 0≤b1≤0.1); coefficient b2 with respect to Ca is 0≤b2≤0.2 (preferably 0≤b2≤0.1); and coefficient b3 with respect to Sr is 0≤b3<0.2 (preferably 0≤b3≤0.1). Conceivably, by tuning the coefficients a and b to fall within the aforementioned ranges, the crystal structure can be further optimized, to thereby further enhance piezoelectric characteristics.

Furthermore, in the alkali niobate-based perovskite-type oxide represented by the aforementioned compositional formula (1) or (2), the ratio of Sc content to Ti content (Sc/Ti) by mole is preferably 0.004 or more and 8 or less. When the ratio of Sc content to Ti content (Sc/Ti) satisfies that condition, conceivably, the provided piezoelectric layer 11 exhibits excellent piezoelectric characteristics and insulation property at high temperatures.

If needed, the alkali niobate-based perovskite oxide according to the present embodiment may contain an additional element. For the purposes of enhancement in piezoelectric characteristics and insulation property, control of sintering temperature, suppression of crystal grain growth, etc., there may be added a composition containing at least one element selected from among, for example, Ta, Ni, Cu, V, Cr, Fe, Co, Zn, Y, Mo, Ru, La, Ce, Pr, Nd, Sm, Eu, Gd, Tb, Dy, Ho, Er, Tm, Yb, Lu, Hf, W, Re, Os, Ir, Ag, and Si.

Next, the secondary phase component contained in the piezoelectric layer 11 will be described in detail. The alkali niobate-based perovskite oxide, serving as a main component of the piezoelectric layer 11, has a cube-like grain shape. Thus, voids are easily provided in the layer, and difficulty is encountered in densification of the piezoelectric layer. From the viewpoint, the piezoelectric layer 11 preferably contains metal oxide particles as a secondary phase component. By incorporating metal oxide particles (i.e., a secondary phase component) into the piezoelectric layer 11 containing the alkali niobate-based perovskite oxide serving as a main component, voids present in the main component of the piezoelectric ceramic layer are filled with the secondary phase component, whereby the yielded piezoelectric layer 11 can possess high density and higher reliability.

The amount of the secondary phase component contained in the piezoelectric layer 11 is preferably 0.1 vol. % or more and 20 vol. % or less, more preferably 0.5 vol. % or more and 5 vol. % or less.

The metal oxide particles, serving as the secondary phase component, is preferably formed of, for example, an oxide containing Mn (manganese) (i.e., manganese-including oxide). By use of manganese oxide, a dense piezoelectric ceramic layer with higher reliability can be yielded. The manganese-including oxide may be an MnOx-type oxide (e.g., MnO, MnO₂, or Mn₃O₄), an Mn—Ti—O oxide (e.g., MnTi₂O₄ oxide, Mn₂TiO₄ oxide, or MnTiO₃ oxide), or a manganese oxide containing a metal element other than manganese, such as an Mn—Nb—O oxide (e.g., Mn₄Nb₂O₉ oxide or an MnNb₂O₆ oxide). Among the aforementioned oxides, an Mn—Ti—O oxide is preferred. The Mn—Ti—O oxide has high affinity with the alkali niobate-based perovskite oxide serving as a primary phase component, to thereby yield the piezoelectric layer 11 with higher reliability. Therefore, by incorporating an Mn—Ti—O oxide (i.e., a secondary phase component) into the piezoelectric layer 11 containing the alkali niobate-based perovskite oxide serving as a main component, the piezoelectric layer 11 with high density and higher reliability can be yielded.

The Mn—Ti—O oxide is represented by, for example, the following compositional formula (3).

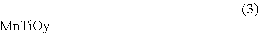

In the aforementioned compositional formula (3), coefficient y satisfies a condition 2≤y≤8. The Mn—Ti—O oxide preferably has a spinel-type or a reverse spinel-type structure. For example, the Mn—Ti—O oxide is preferably MnTi₂O₄ or Mn₂TiO₄.

So long as the structure can be maintained, and variation in characteristics of the compound is allowable, stoichiometric factors may be deviated from the aforementioned standard values. For example, the Mn—Ti—O oxide has a composition represented by the following compositional formula (A) or (B).

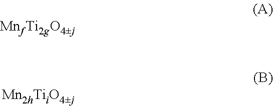

In the aforementioned compositional formulas (A) and (B), coefficients f, g, h, and i are each 0.80<f<1.2, 0.8<g<1.2, 0.8<h<1.2, and 0.8<i<1.2, and coefficient j is a value showing deficiency or excess of oxygen.

Also, in accordance with need, the above oxides may contain an additional element such as Na, K, Zr, Ba, Ca, Sr, Ni, Cu, Ag, or Sc.

The Mn oxide forming the Mn—Ti—O oxide may further contain Sc (scandium) in an amount of 0.05 mol % or more and 5 mol % or less, in addition to Mn (manganese). In this case, the insulation property of the secondary phase can be further enhanced.

The manganese-containing oxide may include a plurality of manganese-containing oxides. The oxide of the secondary phase may include an oxide other than the manganese-containing oxide.

### (Dimensions of Stacked Piezoelectric Ceramic Component)

Next, an example of the dimensions of the stacked piezoelectric ceramic component 10 will be described. The overall dimensions of the component 10 may appropriately be set by a manufacture in accordance with the use of the stacked piezoelectric ceramic component 10, the dimensions and specifications of a device including the stacked piezoelectric ceramic component 10, etc.

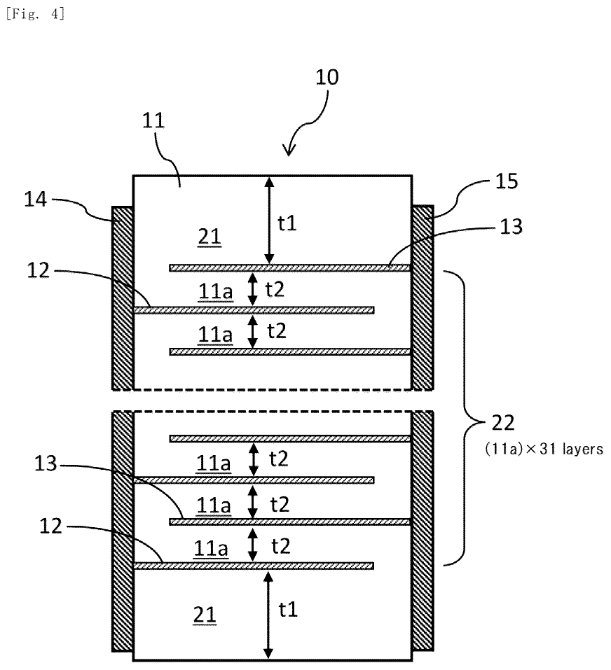

FIG. 3 shows a general configuration, dimensions, etc. of a stacked body 20 according to an embodiment. FIG. 4 shows a general configuration, dimensions, etc. of a stacked piezoelectric ceramic component 10 according to an embodiment. In FIGS. 3 and 4, dimensions are given only as an example, which should not be construed as limiting the actual dimensions.

The stacked body 20 has, for example, a rectangular shape having a length L, a width W, and a height H. In one example, the length L may be adjusted to be 5 mm or more and 120 mm or less, and the width W may be adjusted to be 5 mm or more and 120 mm or less. The height H is appropriately determined in accordance with the thickness t1 of a non-active layer 21, the thickness t2 of a single layer 11a, and the number of the stacked single layers 11a.

The thickness t1 of each non-active layer 21 is 25 μm or more. By setting the thickness t1 of the non-active layer 21 in the above manner, the provided stacked piezoelectric ceramic component 10 can exhibit a high insulation property at high temperature and under a strong electric field. Specifically, as confirmed also in the below-mentioned Examples, an excellent insulation property can be achieved at a high temperature (e.g., about 100° C.) and under a strong electric field (e.g., about 3 kV/mm). In addition, excellent piezoelectric characteristics are achieved under a strong electric field (e.g., about 3 kV/mm).

Preferably, the thickness t1 of each non-active layer 21 is 100 μm or more. By tuning the thickness t1 of the non-active layer 21 in the above manner, the insulation property of the stacked piezoelectric ceramic component 10 can be more enhanced.

More preferably, the thickness t1 of each non-active layer 21 is 200 μm or more and 2,000 μm or less. By tuning the thickness t1 of the non-active layer 21 to 200 μm or more, the insulation property of the stacked piezoelectric ceramic component 10 can be further more enhanced. Also, when the non-active layer 21 is excessively thick, the mechanical strength of the layer decreases due to an increase in residual stress generated after firing. Thus, the thickness t1 is preferably adjusted to 2,000 μm or less.

The thickness t2 of each of the single layers 11a forming an active layer 22 may be adjusted to, for example, 5 μm or more and 300 μm or less. By tuning the thickness t2 of each single layer 11a in the above manner, a stacked body satisfying both insulation property and piezoelectric property can be yielded. Notably, the thickness of the single layer 11a may be equivalent to the distance between internal electrodes 12 and 13, which are adjacent to each other. In other words, the thickness t2 of the single layer 11a may be an inter-electrode distance.

The number of the single layers 11a (i.e., the number of stacking) may be adjusted to, for example, 2 or greater and 200 or smaller (i.e., 2 or more layers and 200 or less layers). By tuning the number of stacked single layers 11a in the above manner, a stacked body satisfying both insulation property and piezoelectric property can be yielded.

The thickness of the internal electrode 12 or 13 may be adjusted to, for example, 0.5 μm or more and 5 μm or less. By tuning the thickness in the above manner, a stacked body satisfying both insulation property and piezoelectric property can be yielded.

### (Method of Manufacturing Stacked Piezoelectric Ceramic Component)

Next will be described an example of the method for manufacturing the stacked piezoelectric ceramic component 10.

Firstly, a plurality of raw material powders of essential ingredients for forming a primary phase (e.g., K₂CO₃ powder, Na₂CO₃ powder, Nb₂O₅ powder, TiO₂ powder, ZrO₂ powder, MnCO₃ powder, BaCO₃ powder, and Sc₂O₃ powder) are provided. Appropriate members of the powders are chosen and weighed so as to attain a target composition. The powder-form raw materials may be an oxide, a carbonate salt, a hydroxide, or the like of an element contained in the primary phase. To the thus-weighed raw material powders, ethanol is added, and the mixture is subjected to wet mixing by means of a ball mill preferably for 15 hours or longer, to thereby yield a slurry. The thus-obtained slurry is dried to form a powder mixture, and the powder mixture is calcined under the conditions, for example, 600 to 1,100° C. in air for 1 to 10 hours, to thereby obtain a powder-form primary phase calcined product.

Subsequently, the thus-obtained primary phase calcined product and secondary phase calcined product are mixed with a dispersant, a binder, and an organic solvent (e.g., toluene), and the resultant mixture is pulverized and mixed, to thereby provide a slurry. Then, the thus-obtained slurry is formed into a sheet through a doctor blade method or the like, to thereby produce ceramic green sheets. The thickness of each ceramic sheet can be regulated by the height of the blade of the doctor blade apparatus. Thus, the thickness of each of the ceramic green sheets for providing the non-active layers 21, and the thickness of each of the ceramic green sheets for providing the single layers 11a of the active layer 22 can be adjusted.

Then, an electrode layer serving as an inner electrode 12 or 13 is formed on a surface of the ceramic green sheet by use of a conductive paste for forming an inner electrode through, for example, screen printing. The electrode layer is predominantly formed of a base metal (e.g., nickel (Ni)). In the present embodiment, Ni is employed as a main component of the base metal. However, a metal other than Ni (nickel), for example, Cu (copper), may be acceptable. Alternatively, an Ni—Cu alloy may also be acceptable. Also, in addition to the main component, an additional element such as Ag (silver), Pd (palladium), and Pt (platinum) may be incorporated.

Next, a plurality of ceramic green sheets each provided with an electrode layer are stacked such that the electrode layers are exposed from both side surfaces in an alternating manner. On each surface of the thus-obtained stacked body, ceramic green sheets each provided with no electrode layer are stacked. The thus-obtained stacked bodies are press-bonded, to thereby yield a stacked body in which ceramic green sheets and electrode layers have been alternatingly stacked.

In the step of yielding the stacked body, the thickness of the non-active layer 21 or the active layer 22 can be modified by regulating the thickness of each ceramic green sheets for providing the non-active layers 21, the thickness of each ceramic green sheets for providing the single layers 11a of the active layer 22, and the number of these layers to target values. In one example (Example 5), a green sheet having a post-firing thickness of 100 μm is used as a non-active layer, and a green sheet having a post-firing thickness of 50 μm is used as an active layer are used, to thereby achieve any desired thickness.

The resultant stacked body is cut into a shape of interest, and then maintained at a temperature, for example, 200 to 400° C. for 2 to 10 hours in an N₂ atmosphere, to thereby perform debindering.

Next, the debindered stacked body is held by means of an alumina setter and maintained for firing at a temperature, for example, 1,000 to 1, 200° C. in a pressure-controlled reducing atmosphere for 2 to 10 hours. The pressure is controlled to a reduction side from Ni/NO equilibrium oxygen partial pressure by the order of magnitude of 1 or greater. Subsequently, the stacked body was maintained for annealing at, for example, 600 to 1,000° C. (more specifically, 800° C.) in an N₂ atmosphere for 1 to 10 hours (e.g., 5 hours). Thus, a stable stacked body can be yielded by firing it being held with an alumina setter and post annealing.

After firing, a side surface of the stacked body is appropriately polished, and a pair of external electrodes 14 and 15 containing Au are formed on the side surface of the stacked body through a technique, for example, sputtering. Instead of the sputtering, in an alternative way, a conductive paste containing Ag, Cu, etc. is applied onto a stacked body, and the stacked body is baked at about 600° C. to 900° C.

The pair of external electrodes 14 and 15 are formed such that they sandwich the stacked body and oppositely face each other. The stacked body equipped with the external electrodes is subjected to a polarization treatment, to thereby yield the stacked piezoelectric ceramic component 10.

Notably, the aforementioned manufacturing method is a merely an exemplary method, and various other steps and treatment conditions for manufacturing the stacked piezoelectric ceramic component 10 may be employed. For example, in the case where a piezoelectric layer 11 contains a secondary phase, a powder-form secondary phase calcined powder may be appropriately prepared by providing a plurality of raw material powders of essential ingredients for forming a secondary phase and using the raw material powders. Then, the thus-obtained secondary phase calcined powder may be added to the primary phase calcined powder at a specific ratio with appropriately mixing, to thereby form the target stacked piezoelectric ceramic component 10.

### (Device Including Stacked Piezoelectric Ceramic Component)

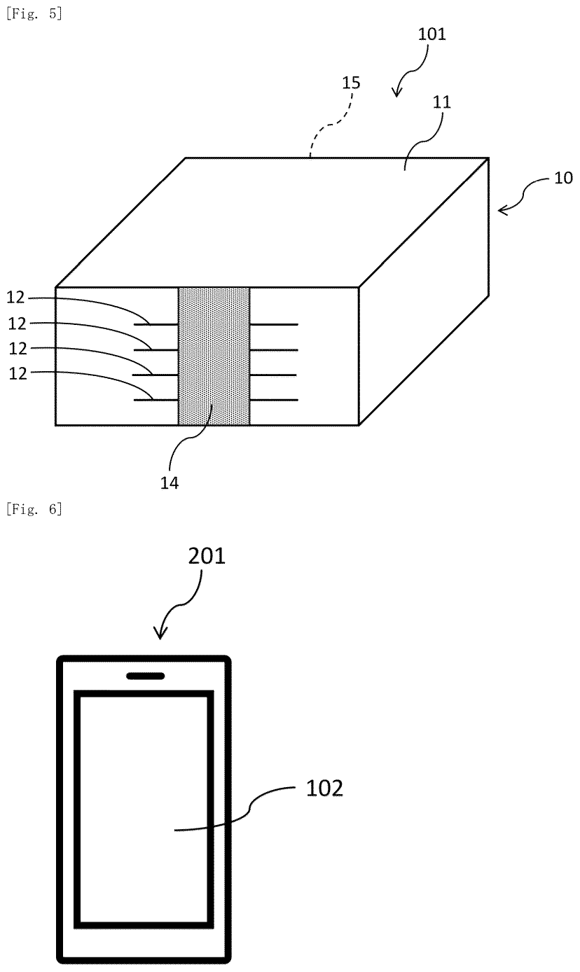

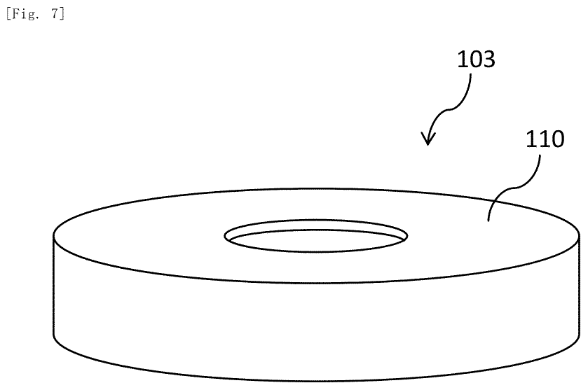

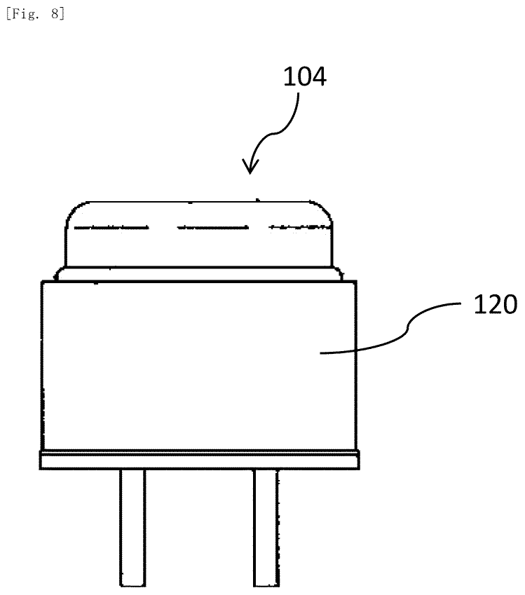

The stacked piezoelectric ceramic component according to the present embodiment can be employed in various devices having a piezoelectric element. No particular limitation is imposed on the device having a piezoelectric element, and examples thereof include an actuator (see FIG. 5), a haptic device (see FIG. 6), a buzzer (see FIG. 7), and an ultrasonic sensor (see FIG. 8).

To the configuration of the actuator, a configuration of a conventionally known piezoelectric actuator can be applied. As a more specific configuration of the actuator, a configuration disclosed in, for example, Patent Document 3 (Japanese Patent Application Laid-Open (kokai) No. 2023-109208) may be applied. FIG. 5 shows a general configuration of an actuator 101 including a stacked piezoelectric ceramic component 10.

To the configuration of the haptic device, a configuration of a conventionally known haptic device including a piezoelectric element can be applied. FIG. 6 shows a general configuration of a tablet terminal 201 including a haptic device 102. The haptic device 102 includes a stacked piezoelectric ceramic component 10.

To the configuration of the buzzer, a configuration of a conventionally known piezoelectric buzzer can be applied. As a more specific configuration of a sound generator, a configuration disclosed in, for example, Patent Document 4 (Japanese Patent Application Laid-Open (kokai) No. 2023-90233) may be applied. FIG. 7 shows a general configuration of a buzzer 103 including a stacked piezoelectric ceramic component 10. The buzzer 103 has a casing 110. In the casing 110, the stacked piezoelectric ceramic component 10 serving as a sound generator is disposed (not illustrated in FIG. 7).

To the configuration of the ultrasonic sensor, a configuration of a conventionally known ultrasonic sensor including a piezoelectric element can be applied. FIG. 8 shows a general configuration of an ultrasonic sensor 104 including a stacked piezoelectric ceramic component 10. The ultrasonic sensor 104 has a hollow exterior body 120. In the hollow exterior body 120, the stacked piezoelectric ceramic component 10 serving as a piezoelectric vibrator (not illustrated in FIG. 8) is disposed.

The device according to the present embodiment has the stacked piezoelectric ceramic component 10. Specific examples of the device according to the present embodiment include an actuator (see FIG. 5), a haptic device (see FIG. 6), a buzzer (see FIG. 7), and an ultrasonic sensor (see FIG. 8).

The device according to the present embodiment has the stacked piezoelectric ceramic component 10 that can exhibit a consistent insulation property at high temperature and under a strong electric field. Thus, the device can exhibit consistently suitable property even under severe conditions (i.e., high-temperature and strong-electric field conditions).

### Examples

The present invention will next be described by way of examples, which should not be construed as limiting the invention thereto.

In the present working examples, a plurality of stacked piezoelectric ceramic components 10 were fabricated. In these components, the thickness of each non-active layer 21 on which a piezoelectric layer 11 had been formed, and the thickness of each single layer 11a were modified. The thus-fabricated components were evaluated in terms of insulation property and piezoelectric characteristics.

### (Manufacturing of Stacked Piezoelectric Ceramic Component)

A stacked piezoelectric ceramic component was manufactured through the following procedure.

For forming a primary phase, K₂CO₃ powder, Na₂CO₃ powder, Nb₂O₅ powder, TiO₂ powder, ZrO₂ powder, MnCO₃ powder, BaCO₃ powder, and Sc₂O₃ powder were provided as raw material powders. The raw material powders were weighed so as to attain a target composition as shown in Table 1. To the thus-weighed raw material powders, an appropriate amount of ethanol was added, and the mixture was subjected to wet mixing by means of a ball mill for 15 hours, to thereby yield a slurry. The thus-obtained slurry was dried to form a powder mixture, and the powder mixture was calcined at 900° C. in air for 5 hours, to thereby obtain a powder-form primary phase calcined product.

TABLE 1

| Ele- | A1 | | M1 | | | | | | |
|---|---|---|---|---|---|---|---|---|---|
| ments | K | Na | Ba | | Nb | Mn | Ti | Zr | Sc |
| Coe- | a | | b | c | d | | | | |
| fficients | a1 | a2 | b1 | | d1 | d2 | d3 | d4 | d5 |
| Comps. | 0.46 | 0.47 | 0.07 | 1.00 | 0.87 | 0.03 | 0.03 | 0.07 | 0 |
| 1 & 2 | | | | | | | | | |
| Exs. 1-10 | 0.46 | 0.47 | 0.07 | 1.00 | 0.87 | 0.03 | 0.03 | 0.07 | 0 |
| Ex. 11 | 0.46 | 0.47 | 0.07 | 1.00 | 0.87 | 0.03 | 0.03 | 0.07 | 0.001 |
| Ex. 12 | 0.46 | 0.47 | 0.07 | 1.00 | 0.86 | 0.03 | 0.03 | 0.07 | 0.01 |

For forming a secondary phase, MnCO₃ powder and TiO₂ powder were provided as raw material powders, and the raw material powders were weighed so attain a target composition of Mn₂TiO₄. To the thus-weighed raw material powders, ethanol was added, and the mixture was subjected to wet mixing by means of a ball mill for 15 hours, to thereby yield a slurry. The thus-obtained slurry was dried to form a powder mixture, and the powder mixture was calcined at 1, 200° C. in air for 5 hours, to thereby obtain a powder-form secondary phase calcined product.

Then, a dispersant, an acrylic binder, and toluene were added to the above-obtained primary phase calcined product and the secondary phase calcined product, and the resultant mixture was pulverized under stirring, to thereby yield a slurry. In this case, the secondary phase calcined product was added so that the amount of Mn₂TiO₄ serving as the secondary phase component with respect to the amount of the alkali niobate-based perovskite-type oxide (i.e., 97.5 vol. %) was adjusted to 1.5 vol. %. Thereafter, the slurry was formed into a sheet through a doctor blading technique or the like, to thereby yield a ceramic green sheet. By regulating the height of the blade of the doctor blade apparatus, ceramic green sheets having different film thickness were manufactured.

Subsequently, a conductive paste for forming an Ni-containing internal electrode was applied through screen printing onto a ceramic green sheet, to thereby yield electrode layers serving as internal electrodes 12 and 13. the thickness of each electrode layer was adjusted to attain the thickness of each of the internal electrodes 12 and 13 after firing to about 2 μm.

Thereafter, a plurality of ceramic green sheets each equipped with an electrode layer were stacked such that the electrode layers were exposed from both side surfaces in an alternating manner. On each surface of the thus-obtained stacked body, ceramic green sheets each provided with no electrode layer were stacked, to thereby yield a new stacked body. The single layers 11a were repeatedly stacked to form a 31-layered stacked body. Then, the thus-obtained stacked body were hot-pressed to thereby yield a stacked body in which ceramic green sheets and electrode layers were alternatingly stacked. In formation of stacked bodies, green sheets were chosen so that the resultant green sheet had a thickness of the values corresponding to the Comparative Examples and the Examples after firing.

The thus-yielded stacked body was cut into pieces of a shape of interest. The resultant pieces were maintained under nitrogen at 300° C. for 5 hours, to thereby perform debindering. After debindering, the stacked body was held by means of an alumina setter, and fired at 1,050° C. in a reducing atmosphere having an oxygen partial pressure of 10-12 atm % for 5 hours. Subsequently, the stacked body was maintained at 800° C. in an N₂ atmosphere for 10 hours, to thereby conduct annealing.

After firing, a side surface of the stacked body 20 was appropriately polished, and a pair of external electrodes 14 and 15 containing Au were formed on the side surface of the stacked body through a technique, for example, sputtering. Then, the stacked body was subjected to a polarization treatment at a DC voltage of 4 kv/mm and 50° C. for 10 minutes, to thereby yield a stacked piezoelectric ceramic component 10.

FIG. 3 shows the general configuration, dimensions, etc. of the thus-fabricated stacked body 20, and FIG. 4 shows the general configuration, dimensions, etc. of the thus-fabricated stacked piezoelectric ceramic component 10. The stacked body 20 had a generally rectangular parallelepiped shape having a length L of 8 mm, a width W of 8 mm, and a height H.

In the Examples and Comparative Examples, the thickness t1 of each non-active layer 21 and the thickness t2 of each single layer 11a were varied respectively. Also, in all the Examples and Comparative Examples, the number of stacked single layers 11a was adjusted to 31. As a result, the height H of the stacked body 20 was varied among the Examples and the Comparative Examples.

Table 2 shows the thickness t1 of each non-active layer 21 and the thickness t2 of each single layer 11a in the Examples and Comparative Examples.

### (Compositional Analysis of Primary Phase)

The piezoelectric layer 11 of the stacked body 20 in each case of the Examples and the Comparative Examples was analyzed by means of an electron probe micro-analyzer (EPMA). In a specific procedure, the image of each stacked body 20 was taken at a magnification of 5,000, and three crystal grains were selected at random in the obtained image. Quantitative analysis was performed at the three crystal grains, and the determined three measurements of quantitation regarding to each element were averaged, to thereby determine the composition of each of the Examples and the Comparative Examples. Table 1 shows the determined compositions.

### (Thickness Measurement of Single Layers and Non-Active Layers)

A cross-section of each of the stacked bodies 20 of the Examples and the Comparative Examples was mirror-polished, and a backscattered electron image of the cross-section was taken under a scanning electron microscope (SEM) at a magnification of 100. Taking of images was conducted at the following sites: centers of the uppermost layer and the lowermost layer of the stacked body 20 (in the case of non-active layers 21) and centers of the first layer, the 16th layer, and the 31st layer selected from the single layers 11a (formed of 31 layers in total), with an area of 500 μm×500 μm from each center. Notably, based on the image contrast in the backscattered electron image, a piezoelectric ceramic layer (the single layer or the non-active layer) can be easily differentiated from the internal electrode.

The thickness t1 of the non-active layer 21 was an averaged value of the thickness of the uppermost layer and that of the lowermost layer at a center position. The thickness t2 of the single layer 11a was an averaged value derived from the distance between the internal electrodes 12 and 13 at the center position in the first layer, the 16th layer, and the 31st layer of the single layers 11a. Table 2 shows the thickness measurements of t1 and t2 calculated through the above procedures in the Examples and Comparative Examples.

### (Evaluation of Piezoelectric Characteristics)

The stacked piezoelectric ceramic components 10 of the Examples and Comparative Examples were tested by means of a laser Doppler vibrometer under unipolar drive conditions (specifically, application of a positive electric field (maximum electric field Emax of +3 kV/mm) in the form of a sinusoidal wave at a frequency of 0.1 Hz to a sample at room temperature), to thereby determine the displacement amount S of the stacked body in a longitudinal direction. The displacement amount S was divided by the electric field E, to thereby derive an S/E value at each electric field. Table 2 shows the results.

The thus-obtained S/E value serves as an index for the displacement (i.e., a piezoelectric characteristic). The greater the S/E value, the more excellent the piezoelectric characteristics of the sample. In the Comparative Examples, in which the thickness t1 of each non-active layer 21 was small (i.e., t1=16 μm), the S/E value was found to be smaller as compared with the Examples. Also, in Examples 1 to 12, in which the thickness t1 of each non-active layer 21 was 28 μm or greater, the S/E value was found to be 300 μm/V or greater.

### (Measurement of Insulation Resistance)

The insulation resistance (Ω·m) of the stacked piezoelectric ceramic components 10 of the Examples and Comparative Examples was measured. In a specific procedure, a sample of the stacked piezoelectric ceramic component 10 was placed in silicone oil at 100° C., and a DC voltage of 3 kV/mm was applied to the sample. One minute after, insulation resistance (Ω·m) was measured. Table 2 shows the results.

An insulation resistance measurement was assessed on the basis of the following ratings. In Table 2, the assessment is denoted by “O” or “X”
O (good): insulation resistance (Ω·m) of 1×10⁵ (Ω·m) or higher
X (poor): insulation resistance (Ω·m) lower than 1×10⁵ (22.m)

In Examples 1 to 12, in which the thickness t1 of each non-active layer 21 was 28 μm or greater, a suitable insulation property was found to be achieved. In Examples 4 to 7, in which the thickness t1 of each non-active layer 21 was 100 μm or greater, a more enhanced insulation property was found to be achieved, as compared with Examples 1 to 3. In Examples 8 to 10, in which the thickness t1 of each non-active layer 21 was 200 μm or greater, an enhancement in insulation property was confirmed, as compared with Examples 4 to 7.

According to the results of Examples 4 to 6, it is indicated that the thickness t2 of each single layer 11a does not considerably influences over insulation resistance.

Table 2 shows addition of Sc, and Sc content (mol %) of a piezoelectric layer to which Sc was added. In Examples 11 and 12, in which Sc was added, a rise in insulation resistance was confirmed, as compared with Example 3, in which the thickness t1 of the non-active layer 21 and the thickness t2 of the single layer 11a were almost equivalent. In consideration of the results, addition of Sc to the primary phase of the piezoelectric layer 11 conceivably leads to a further enhancement in insulation property.

TABLE 2

| | | | Sc | Insulation | | |
|---|---|---|---|---|---|---|
| | Thickness t1 of non- | Thickness t2 of single | (mol | resistance | | |
| | active layer (μm) | layer (μm) | %)/— | (Ω • m) | S/E (pm/V) | Score |
| Comp. 1 | 16 | 16 | — | 2 × 10⁴ | 220 | X |
| Comp. 2 | 16 | 28 | — | 1 × 10⁴ | 240 | X |
| Ex. 1 | 28 | 28 | — | 4 × 10⁶ | 321 | O |
| Ex. 2 | 49 | 29 | — | 6 × 10⁶ | 319 | O |
| Ex. 3 | 70 | 28 | — | 8 × 10⁶ | 314 | O |
| Ex. 4 | 101 | 28 | — | 1 × 10⁷ | 308 | O |
| Ex. 5 | 100 | 50 | — | 2 × 10⁷ | 305 | O |
| Ex. 6 | 103 | 103 | — | 1 × 10⁷ | 302 | O |
| Ex. 7 | 151 | 27 | — | 6 × 10⁷ | 311 | O |
| Ex. 8 | 202 | 28 | — | 3 × 10⁸ | 307 | O |
| Ex. 9 | 253 | 29 | — | 3 × 10⁸ | 305 | O |
| Ex. 10 | 301 | 28 | — | 4 × 10⁸ | 301 | O |
| Ex. 11 | 69 | 28 | 0.1 | 1 × 10⁷ | 318 | O |
| Ex. 12 | 72 | 28 | 1.0 | 3 × 10⁸ | 319 | O |

The embodiments disclosed in the specification should be given for the illustration and non-limitative purposes, from all aspects. The scope of the present invention is defined not by the above description but by the appended claims, and are intended to encompass equivalents to the claims and any modifications within the scope of the invention. Furthermore, technical means or configurations provided through combination of the means and configuration of the different embodiments which have been described in the present specification are also encompassed within the scope of the present invention.

### DESCRIPTION OF REFERENCE SYMBOLS

10: stacked piezoelectric ceramic component
11: piezoelectric layer (piezoelectric ceramic layer)
11a: single layer
12: internal electrode (electrode)
13: internal electrode (electrode)
14: external electrode
15: external electrode
20: stacked body
21: non-active layer
22: active layer
101: actuator
102: haptic device
103: buzzer
104: ultrasonic sensor

1. A stacked piezoelectric ceramic component comprising a stacked body which includes a plurality of electrodes and piezoelectric ceramic layers stacked such that each of the electrodes is disposed between the piezoelectric ceramic layers, the piezoelectric ceramic layers containing alkali niobate-based perovskite-type oxide as a main component,
wherein a portion of the piezoelectric ceramic layers, which portion is not sandwiched between the plurality of stacked electrodes serves as a non-active layer, and
wherein the non-active layer has a thickness of 25 μm or greater.

2. The stacked piezoelectric ceramic component according to claim 1, wherein the electrodes contain nickel as a main component.

3. The stacked piezoelectric ceramic component according to claim 1, wherein the non-active layer has a thickness of 100 μm or greater.

4. The stacked piezoelectric ceramic component according to claim 3, wherein the non-active layer has a thickness of 200 μm or greater and 2,000 μm or smaller.

5. The stacked piezoelectric ceramic component according to claim 1, wherein the piezoelectric ceramic layer contains a primary phase component containing the alkali niobate-based perovskite-type oxide, and
a secondary phase component containing an oxide containing manganese and titanium.

6. The stacked piezoelectric ceramic component according to claim 5, wherein the alkali niobate-based perovskite-type oxide includes manganese and titanium.

7. The stacked piezoelectric ceramic component according to claim 6, wherein the alkali niobate-based perovskite-type oxide further includes scandium.

8. A device comprising a stacked piezoelectric ceramic component as recited in claim 1.

9. The device according to claim 8, which is any of an actuator, a haptic device, a buzzer, and an ultrasonic sensor.
